(19) United States
(12) Patent Application Publication
(10) Pub. No.: US 2020/0013880 A1
(43) Pub. Date: Jan. 9, 2020

(54) INTEGRATED CIRCUIT DEVICE WITH FARADAY SHIELD

(71) Applicant: Silterra Malaysia Sdn. Bhd., Kulim (MY)

(72) Inventors: Chiew Nyuk Ho, Kulim (MY); Arjun Kumar Kantimahanti, Kulim (MY); Venkatesh A/L Madhaven, Kulim (MY); Seok Man Yun, Kulim (MY); Saw Li Lee, Kulim (MY); Thart Liang Ong, Kulim (MY)

(21) Appl. No.: 16/504,121

(22) Filed: Jul. 5, 2019

(30) Foreign Application Priority Data
Jul. 9, 2018 (MY) PI 2018702390

(51) Int. Cl. H01L 29/66; H01L 23/60; H01L 29/786; H01L 29/49

(52) U.S. Cl. CPC H01L 29/66681; H01L 29/4975; H01L 29/7869; H01L 23/60

(57) ABSTRACT

An integrated circuit device that includes a substrate as a base of the integrated circuit device, a semiconductor layer disposed on top of the substrate, an isolation layer disposed on top of the semiconductor layer, a plurality of metals disposed above the isolation layer, a transistor including a source and drain region positioned in the semiconductor layer, and a gate electrode connected to the source and drain region and positioned in the isolation layer, wherein the source and drain region, and gate electrode are respectively connected to the metals by electrical contacts, and a Faraday shield positioned laterally between the gate electrode and the drain region in the isolation layer. The Faraday shield is connected to one of the metals through at least one conductive interconnect produced by a damascene process such that the interconnect forms a continuous connection to the metal from the Faraday shield.

### CROSS-REFERENCE TO RELATED APPLICATION

The instant application claims priority to Malaysia Patent Application Ser. No. PI 2018702390 filed Jul. 9, 2018, the entire specification of which is expressly incorporated herein by reference.

### FIELD OF THE INVENTION

This invention relates to an integrated circuit device. In more particular, the invention is about a laterally diffused metal oxide semiconductor device.

### BACKGROUND OF THE INVENTION

The application of laterally diffused metal oxide semiconductor, LDMOS devices in microwave/RF power amplifiers offers several advantages, including high linearity and efficiency, high gain, excellent reliability and competitive cost. In a RF-LDMOS device, a Faraday shield is applied in between a gate and drain for mitigating high electric field at the gate and drain edge, as well as reducing reverse transfer capacitance, which is the gate to drain capacitance, thereby enhancing RF performance.

An example of a LDMOS device is described in U.S. Pat. No. 9,064,868. This integrated circuit device comprises a transistor comprising a gate electrode and a drain region formed in a semiconducting substrate, an isolation structure formed in the substrate, and a Faraday shield positioned laterally between the gate electrode and the drain region, and above the isolation structure. The Faraday shield is formed of a plurality of vertically stacked conductive features, wherein each of the plurality of vertically stacked conductive features is positioned in a separate layer of insulating material.

U.S. Patent Application Publication No. US20140042538 also disclosed a radio frequency LDMOS device having a substrate, a p-type epitaxial layer on the substrate, a p-type well in a first portion of the p-type epitaxial layer, a lightly doped n-type drain region in a second portion of the p-type epitaxial layer, a moderately doped n-type region in a first portion of the lightly doped n-type drain region, a heavily doped n-type drain region in a second portion of the lightly doped n-type drain region, and a heavily doped n-type source region in an upper portion of the p-type well. This RF LDMOS device also includes a gate oxide layer covering a portion of the p-type epitaxial layer between the heavily doped n-type source region and the lightly doped n-type drain region, a polysilicon gate covering the gate oxide layer, an oxide layer covering the polysilicon gate and a portion of the moderately doped n-type region, and a Faraday shield covering a portion of the oxide layer.

Generally, the Faraday shield is connected to a metal by multiple conventional electrical contacts. Since the electrical contacts are separate components, there is no continuous current flow from the Faraday shield to the metal, and the conductive surface is small. This drawback leads to low current capacity transmission.

### SUMMARY OF THE INVENTION

The present invention relates to an integrated circuit device comprising a plurality of metals disposed on surface of the integrated circuit device, and a Faraday shield connected to one of the metals through at least one conductive interconnect, wherein the interconnect is produced by a damascene process and forms a continuous connection to the metal from the Faraday shield.

In a preferred embodiment of the present invention, the integrated circuit device further comprises a substrate as a base of the integrated circuit device, a semiconductor layer disposed on top of the substrate, an isolation layer positioned on top of the semiconductor layer, wherein the metals are disposed above the isolation layer, and a transistor including a source and drain region, and a gate electrode.

In one embodiment of the present invention, the interconnect further comprises a conductive material layer extended from the metal to the Faraday shield in which the interconnect is connected thereto.

The present invention further comprises at least one mask layer for joining more than one interconnects together to form the continuous connection to the metal layer from the Faraday shield.

It is preferred that the Faraday shield is positioned laterally between the gate electrode and the drain region in the isolation layer.

In a preferred embodiment, the Faraday shield consists of a plurality of insulative layers and at least one conductive layer.

It is preferred that the insulative layer is any one or a combination of silicon nitride and silicon rich oxide.

Preferably, the conductive layer is any one or combination of titanium nitride, tungsten and silicide.

The semiconductor layer is preferred to be an epitaxial layer.

Preferably, the source, drain and gate electrode are respectively connected to the metals by an electrical contact.

A main purpose of this invention is to introduce a solution to existing integrated circuit devices, especially laterally diffused metal oxide semiconductor devices that utilizes a plurality of electrical contacts for connecting the Faraday shield to a metal. Such conventional method does not provide continuous and large surface area for current flow. The present invention suggested the use of an interconnect that allows continuous and bulk current flow. In addition, it also provides large surface area for current flow. It is preferred that a single interconnect is utilized in the present invention such that it eliminates the need for installation or formation of multiple electric contacts. However, the present invention also supports the use of more than one interconnect by connecting the interconnects together via at least one mask layer. The damascene process for forming the interconnect allows the interconnect that connects the Faraday shield to a metal to be manufactured at the same time as the installation or formation of other electrical contacts that connect other components, including the electrical contacts which connects the drain and source region, and the gate electrode to the metals respectively. The continuous interconnect formed through the damascene process is simple and less complicated as the conventional method that requires installation or formation of several electric contacts which can only support low current density. Moreover, more than one interconnect can be formed through the present invention to enhance the continuation of connection from the Faraday shield to the metal with different conductive materials. Further, the continuous interconnect allows the fabrication of a smaller cell for the integrated circuit device.

### BRIEF DESCRIPTION OF THE DRAWINGS

FIG. 1 shows a LDMOS device with a single and continuous interconnect connecting the Faraday shield to a metal.

FIG. 2 shows a LDMOS device with more than one interconnects in which one of the interconnects is formed by a conductive material layer extended from the metal to the Faraday shield in which the interconnect is connected thereto.

### DETAILED DESCRIPTION OF THE INVENTION

For a better understanding of the invention, preferred embodiments of the invention that are illustrated in the accompanying drawings will be described in detail.

The present invention discloses an integrated circuit device. In more particular, the integrated circuit device is a laterally diffused metal oxide semiconductor, LDMOS device. The LDMOS device is suitable for use in radio frequency, RF devices and therefore, the integrated circuit device can be a RF-LDMOS device.

In a preferred embodiment, the present invention comprises a substrate (101) as a base of the integrated circuit device. On top of the substrate (101) is a semiconductor layer (102) sandwiched between the substrate (101) and an isolation layer (103). It is preferred that the semiconductor layer (102) is an epitaxial layer. A plurality of metals (110a, 110b, 110c, 110d) are disposed above the isolation layer (103). A transistor including a source (107) and drain (108) region, and a gate electrode (109) employed in the present invention. The source (107) and drain (108) region, and gate electrode (109) are respectively connected to the metals (110a, 110b, 110c, 110d) by electrical contacts (113a, 113b, 113c).

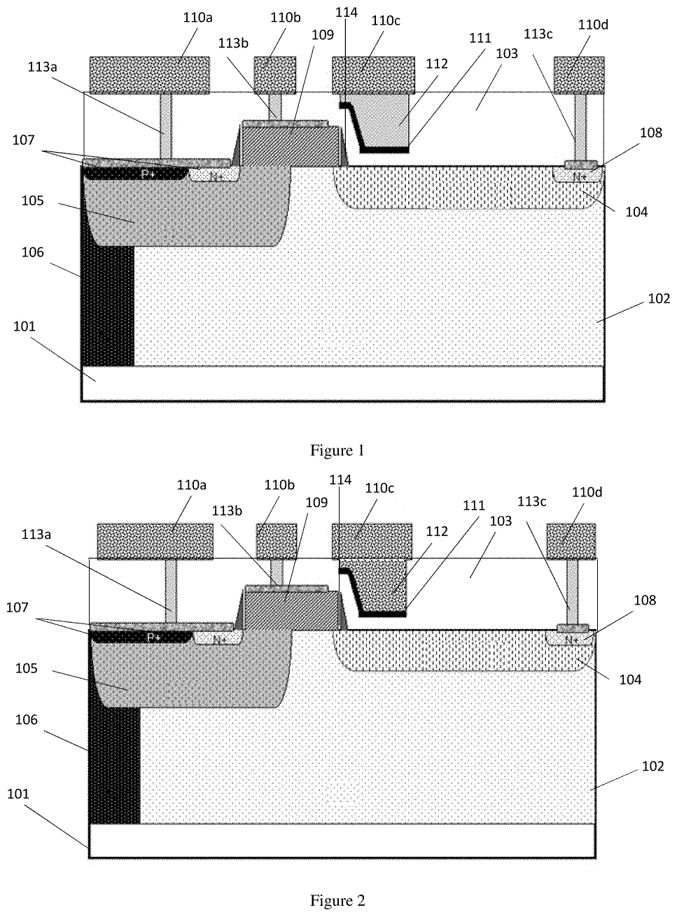

Referring to FIG. 1, a Faraday shield (111) is disposed laterally between the gate electrode (109) and drain (108) region in the isolation layer (103). The Faraday shield (111) serves to mitigate high electric field at edge of the gate electrode (109) and drain (108) region, as well as reduce the reverse transfer capacitance from the gate electrode (109) to the drain (108) region for enhancing radio frequency performance of the present invention. The Faraday shield (111) consists of a plurality of insulative layers and at least one conductive layer. Preferably, the insulative layer is any one or a combination of silicon nitride and silicon rich oxide, whereas the conductive layer is any one or combination of titanium nitride, tungsten and silicide.

A primary feature of the present invention is the incorporation of a continuous conductive interconnect (112) that connects the Faraday shield (111) to one of the metals (110c) above the Faraday shield (111). The interconnect (112) as illustrated in FIG. 1 is a single and continuous component in between the Faraday shield (111) and the metal (110c). Produced by the damascene process, the interconnect (112) has a large surface area for current flow.

In another embodiment of the present invention as illustrated in FIG. 2, the integrated circuit device comprises more than one interconnect (112). One of the interconnects (112) can be formed of a conductive material layer that extends from the metal (110c) to the Faraday shield (111) in which the Faraday shield (111) is connected thereto. The textures of the metal (110c) and outer surface of the interconnect (112) are the same as illustrated in FIG. 2, indicating, the interconnect (112) is the conductive material layer that extends from the metal (110c). This approach enhances the continuation connection between the Faraday shield (111) and the metal (110c). It should be noted that there is no restriction on the material used for forming the interconnect (112). Any conductive material is applicable to form the interconnect (112) depending on the needs of the users or manufacturers. The embodiment as depicted in FIG. 2 enables different conductive materials to be used as the interconnects (112) in a situation where there is more than one interconnect (112).

According to the preferred embodiment of the present invention as depicted in FIG. 1, the semiconductor layer (102) is formed with at least one n-drift region (104) below the drain region (108). Further, the semiconductor layer (102) is formed with at least one p-well region (105) below the source (107) region. In addition, the semiconductor layer (102) is formed with a p-sinker region (106) for connecting all p+ substrates from the p-well region (105) and the source (107) region. There is also a spacer (114) at each of the two lateral sides of the gate electrode (109) for isolating the gate electrode (109) from the source (107) and drain (108) region.

The process flow of producing the present invention starts from forming the transistor after the substrate (101), semiconductor layer (102) and isolation layer (103) are formed. The conductive feature on the source (107) and drain (108) region, as well as the gate electrode (109) are formed via salicidation process that involves the reaction of a thin metal film with silicon in the active regions of the device, whereby metal silicide contacts are formed through a series of annealing, etching processes, or a combination thereof.

Following the salicidation process, the Faraday shield (111) is formed by multiple dielectric films and a conductive film. The interconnect (112) is then formed through the damascene processes that starts from etching the dielectric layer to form a recess according to predetermined dimensions for the interconnect (112) on top of the Faraday shield (111). A barrier layer is deposited into the base of the recess to separate the recess from the Faraday shield (111) for preventing diffusion of the material to be deposited into the recess.

The conductive material that forms the interconnect (112) is then deposited into the recess. Applicable conductive materials include copper. The deposition of the conductive material can be carried out by the electroplating process. In a final step of the damascene process, the surface of the interconnect (112) is planarized using chemical mechanical planarization, CMP.

Such process of forming the interconnect (112) allows simultaneously formation of other electric contacts (113a, 113b, 113c) for connecting to other components including the source (107) and drain (108) region, as well as the gate electrode (109). In another preferred embodiment of the present invention as illustrated in FIG. 2 in which there is more than one interconnect (112), the interconnect (112) being a conductive material layer that extends from the metal (110c) to the Faraday shield (111) can be formed separately at a different time from the electric contact (113a, 113b, 113c) with the use of at least one mask layer. With this approach, different conductive materials can be used depending on the requirement. Single interconnect (112) can be extended to dual interconnects or more. Formation of the metals (110a, 110b, 110c, 110d), other contacts and vias are also performed after the formation of the interconnect (112).

What is claimed is:

1. An integrated circuit device, comprising:
a plurality of metals disposed on surface of the integrated circuit device; and
a Faraday shield connected to one of the metals through at least one conductive interconnect;
wherein the interconnect is produced by a damascene process and forms a continuous connection to one of the metals from the Faraday shield.

2. The integrated circuit device according to claim 1, further comprising:
a substrate as a base of the integrated circuit device;
a semiconductor layer disposed on top of the substrate;
an isolation layer positioned on top of the semiconductor layer;
wherein the plurality of metals are disposed above the isolation layer; and
a transistor including a source and drain region, and a gate electrode.

3. The integrated circuit device according to claim 1, wherein the interconnect further comprises a conductive material layer extended from one of the metals to the Faraday shield in which the interconnect is connected thereto.

4. The integrated circuit device according to claim 1, further comprising:
at least one mask layer for joining more than one interconnect together to form the continuous connection to one of the metals from the Faraday shield.

5. The integrated circuit device according to claim 1, wherein the Faraday shield is positioned laterally between the gate electrode and the drain region in the isolation layer.

6. The integrated circuit device according to claim 1, wherein the Faraday shield consists of a plurality of insulative layers and a conductive layer.

7. The integrated circuit device according to claim 6, wherein the insulative layer is any one or a combination of silicon nitride and silicon rich oxide.

8. The integrated circuit device according to claim 6, wherein the conductive layer is any one or combination of titanium nitride, tungsten and silicide.

9. The integrated circuit device according to claim 2, wherein the semiconductor layer is an epitaxial layer.

10. The integrated circuit device according to claim 2, wherein the source and drain region and the gate electrode are respectively connected to one of the metals by an electrical contact.
